(19) United States
(12) Patent Application Publication
(10) Pub. No.: US 2005/0255648 A1
(43) Pub. Date: Nov. 17, 2005

(54) Silicon based substrate hafnium oxide top environmental/thermal top barrier layer and method for preparing

(76) Inventors: Tania Bhatia, Middletown, CT (US); Ellen Y. Sun, South Windsor, CT (US)

Correspondence Address: BACHMAN & LAPOINTE, P.C., 900 CHAPEL STREET, SUITE 1201, NEW HAVEN, CT, 06510, US

(21) Appl. No.: 10/846,968

(22) Filed: May 13, 2004

(51) Int. Cl. H01L 21/8238; H01L 21/8242; H01L 21/31; H01L 21/469

(52) U.S. Cl. 438/218; 438/240; 438/778

(57) ABSTRACT

A top barrier layer for a silicon containing substrate which inhibits the formation of gaseous species of silicon when exposed to a high temperature aqueous environment and comprises at least 65 mol % hafnium oxide.

This invention was made with government support under Contract No. N00014-01-C-0032 awarded by Office of Naval Research. The government may have certain rights in the invention.

### BACKGROUND OF THE INVENTION

The present invention relates to an article comprising a substrate containing silicon and a top barrier layer which functions as a protective environmental/thermal barrier coating and, more particularly, a top barrier layer which inhibits the formation of gaseous species of Si, particularly Si(OH)ₓ when the article is exposed to high temperature, aqueous (steam) environments.

Ceramic materials containing silicon have been proposed for structures used in high temperature applications as, for example, gas turbine engines, heat exchangers, internal combustion engines, and the like. A particularly useful application for these materials is for use in gas turbine engines which operate at high temperatures water vapor rich environments. It has been found that these silicon containing substrates can recede and lose mass as a result of a formation volatile Si species, particularly Si(OH)ₓ and SiO when exposed to high temperature, high velocity and high pressure steam as is found in gas turbines engines. For example, silicon carbide components when exposed to both fuel lean and fuel rich combustion environments of approximately 10 Atm total pressure at 1200° C. with gas velocities ranging 30-90 m/s will exhibit weight loss and recession at a rate of approximately 10-15 mils per 1000 hrs. It is believed that the process involves oxidation of the silicon carbide to form silica on the surface of the silicon carbide followed by reaction of the silica with steam to form volatile species of silicon such as Si(OH). Alkaline-earth aluminosilicates of barium, strontuim and mixtures thereof such as Barium Strontium Alumino Silicate (BSAS), are current state-of-the art top layer candidates and are the subject of many patents and technical literature in the area of environmental barrier coatings. It has been found that BSAS recedes at a finite rate in engine conditions (typically around 9 μm/1000 hrs around 1200° C.

Naturally it would be highly desirable to provide a top external barrier coating for silicon containing substrates which would inhibit the formation of volatile silicon species, Si(OH)ₓ and SiO, and thereby reduce recession and mass loss.

Accordingly, it is the principle object of the present invention to provide an article comprising a silicon containing substrate with a top barrier layer which inhibits the formation of gaseous species of Si, particularly Si(OH)ₓ, when the article is exposed to a high temperature, steam environment.

A second object of this invention is to provide an article comprising a substrate with a top barrier layer providing thermal/environmental protection, such top layer closely matching the coefficient of thermal expansion of the substrate.

It is a further object of the present invention to provide a method for producing an article as aforesaid.

### SUMMARY OF THE INVENTION

The present invention relates to an article comprising a silicon containing substrate having a top barrier layer on the substrate, wherein the top barrier layer functions to both inhibit the formation of undesirable gaseous species of silicon when the article is exposed to a high temperature, steam environment and to provide thermal protection. By high temperatures is meant the temperature at which the Si in the substrate forms Si(OH)ₓ and/or SiO in an aqueous environment. By aqueous environment is meant a high pressure/high velocity water vapor environment. The silicon containing substrate is preferably a ceramic material containing silicon (for example, monolithic silicon carbide, silicon nitride, and composites of Silicon carbide and silicon nitride). The top barrier layer is characterized by a coefficient of thermal expansion which is within plus or minus 3.0 ppm per degree centigrade of the coefficient of expansion of the silicon containing substrate. The top barrier layer in accordance with the present invention comprises hafnium oxide. In a preferred embodiment of the present invention the article can include one or more intermediate layers between the silicon based substrate and the top barrier layer. The intermediate layer(s) serve(s) to provide enhanced adherence between the top barrier layer and the substrate and/or to prevent reactions between the top barrier layer and the substrate.

The invention further relates to a method for producing an article comprising a silicon containing substrate and a top barrier layer which inhibits the formation of gaseous species of silicon and/or provides thermal protection when the article is exposed to a high temperature, aqueous environment as defined above.

Further objects and advantages of the present invention will appear hereinbelow from the following detailed description.

### BRIEF DESCRIPTION OF THE DRAWINGS

FIG. 1 is a graph showing the stability of the top barrier layer of the present invention with respect to recession and mass loss; and

FIGS. 2a and b are photomicrographs through two samples top barrier layer in accordance with the present invention on a silicon carbide substrate (SiC fiber reinforced SiC matrix composite).

### DETAILED DESCRIPTION

The present invention relates to an article comprising a silicon substrate and a top barrier layer, wherein the top barrier layer inhibits the formation of gaseous species of silicon when the article is exposed to a high temperature, aqueous environment. The invention also relates to a method for producing the aforesaid article. In addition, it should be appreciated that while the top layer is particularly directed to an environmental barrier layer, the top layer also functions as a thermal barrier layer and thus the present invention broadly encompasses the use of environmental/thermal top barrier layers on silicon containing substrates.

According to the present invention, the silicon containing substrate comprises a silicon-based ceramic substrate. In a preferred embodiment, the silicon containing substrate is a silicon containing ceramic material as, for example, silicon carbide and silicon nitride. In accordance with a particular embodiment of the present invention, the silicon containing ceramic substrate comprises a silicon containing matrix with reinforcing materials such as fibers, particles and the like and, more particularly, a silicon based matrix which is fiber-reinforced. In another embodiment of the invention, the Si containing ceramic substrate might be monolithic silicon carbide or silicon nitride.

The top barrier layer of the present invention which is particularly useful in the article of the present invention comprises at least 65 mol % hafnium oxide. In accordance with a preferred embodiment, monoclinic hafnium oxide is preferred. In a particular embodiment, the top barrier layer further comprises up to 30 mol % of at least one of an oxide selected from the group consisting of oxides of Zr, Ti, Nb, Ta, Ce and mixtures thereof, balance hafnium oxide. In a further embodiment, the top layer comprises up to 5 mol % of at least one of an oxide selected from the group consisting of oxides of rare earth elements, Y, Sc, Al, Si and mixtures thereof, balance hafnium oxide. In a still further embodiment, the top barrier layer comprises up to 30 mol % of at least one of an oxide selected from the group consisting of oxides of Zr, Ti, Nb, Ta, Ce and mixtures thereof; up to 5 mol % of at least one of an oxide selected from the group consisting of oxides of rare earth elements, Y, Sc and mixtures thereof; and balance hafnium oxide. Particularly useful rare earth elements include La, Gd, Sm, Lu, Yb, Er, Pr, Pm, Dy, Ho, Eu and mixtures thereof.

It is an important feature of the present invention to maintain compatibility between the coefficient of thermal expansion of the silicon containing substrate and the top barrier layer and any intermediate layer(s). In accordance with the present invention it has been found that the coefficient of thermal expansion of the top barrier layer should be within ±3.0 ppm per degrees centigrade, preferably ±2.0 ppm per degrees centigrade, of the coefficient of thermal expansion of the silicon containing substrate. When using a silicon containing ceramic substrate such as a silicon carbide matrix or a silicon nitride matrix with or without reinforcing fibers as described above in combination with the monoclinic hafnium oxide top barrier layer of the present invention, the desired compatibility with respect to expansion coefficient between the silicon containing substrate and the top barrier layer should be ±2.00 ppm per degrees centigrade.

The top barrier layer should be present in the article at a thickness of greater than or equal to about 0.5 mils (0.0005 inch), preferably between about 2 to about 30 mils and ideally between about 3 to about 5 mils. The top barrier layer may be applied to the silicon containing substrate by any suitable manner known in the art, such as, thermal spraying, slurry coating, vapor deposition (chemical and physical). In a further embodiment of the article of the present invention, an intermediate layer can be provided between the silicon containing substrate and the top barrier layer. The intermediate layer(s) serve(s) to provide enhanced adhesion between the top barrier layer and the substrate and/or to prevent reactions between the top barrier layer and the substrate. The intermediate layer consists of, for example, a layer selected from the group consisting of HfSiO₄, BaSiO₂, SrSiO₂, aluminum silicate, yttrium silicate, rare earth silicates, mullite, alkaline earth aluminosilicates of barium strontium, and mixtures thereof. The intermediate layer could also consist of a mixture of Si and HfO₂ and/or HfSiO₄. The thickness of the intermediate layer is typical to those described above with regard to the top barrier layer and the intermediate layer may likewise be disposed in any manner known in the prior art as described herein below with regard to the top barrier layer. In addition to the intermediate layer, a bond layer may be provided between the silicon containing substrate and the top barrier layer or, if used, the intermediate layer. A suitable bond layer comprises silicon metal in a thickness of up to 6 mils. Another manifestation of the bond layer could include a mixture of Si and HfO₂ and/or HfSiO₄.

The method of the present invention comprises providing a silicon containing substrate and applying a top barrier layer wherein the top barrier layer inhibits the formation of gaseous species of silicon when the article is exposed to a high temperature, aqueous environment. In accordance with the present invention the top barrier layer can be applied by thermal spraying. It has been found that the top barrier layer may be sprayed at room temperature. However, when the substrate is heated, the quality of the coating is enhanced. Thermal sprayed of between about 400° C. to 1200° C. helps equilibrate as-sprayed, splat quenched, microstructure and to provide a means to manage stresses which control delamination.

The silicon bond layer may be applied directly to the surface of the silicon containing substrate by thermal spraying at approximately 870° C. to a thickness of up to 6 mils.

The intermediate layer may be applied between the substrate and the top barrier layer or between the bond layer and top barrier layer by thermal spraying in the same manner described above with respect to the top barrier layer. As noted above, the preferred intermediate layers comprise HfSiO, BaSiO₂, SrSiO₂, aluminum silicate, yttrium silicate, rare earth silicates, barium strontium aluminosilicate, mullite-barium strontium aluminosilicate and mixtures thereof.

The advantages of the article of the present invention will become clear from consideration of the following example.

### EXAMPLE 1

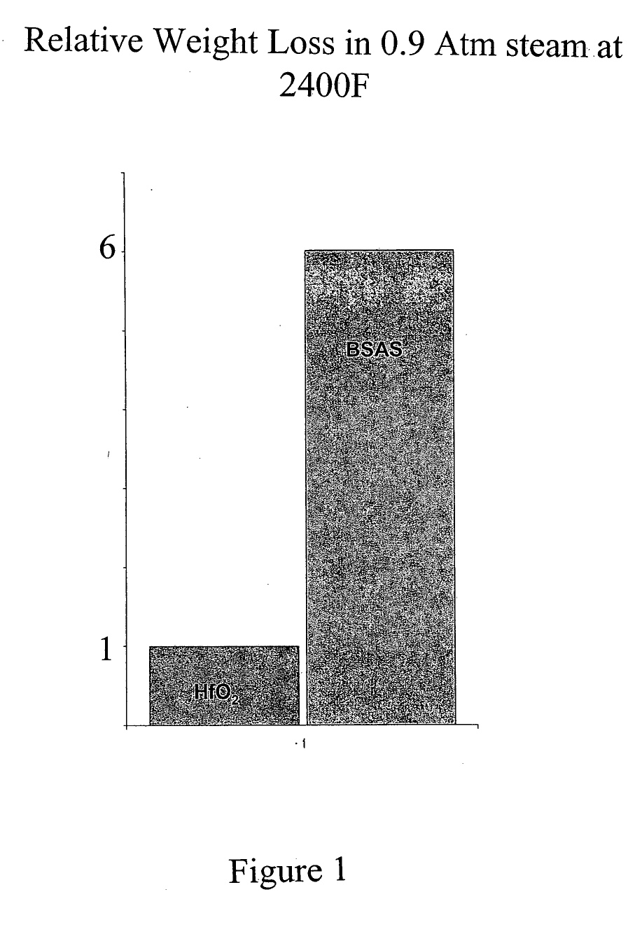

Dense samples of HfO2 was prepared by hot pressing HfO2 powders in a 3×3″ square panels in a graphite die. The powders were consolidated using a pressure of 3 ksi to a temperature of 1600° C. for 2 hours. The heat up rates used were 10° C./min. Post hot-pressing, the sample was heat treated to 1600° C./50 hrs in air. In addition, dense samples of BSAS was prepared by hot pressing pre-reacted BSAS (BaAl2Si208) powders in a 3×3″ square panels in a graphite die The powders were consolidated using a pressure of 4 ksi to a temperature of 1400° C. for 2 hours. The heat up rates used were 15° C./min. Post hot-pressing, the sample was heat treated to 1500° C./50 hrs in air. Rectangular Samples of HfO₂ and BSAS were cut out of the hot-pressed and heat treated panels and suspended in a furnace with flowing steam (90% steam). The temperature of the exposure was 1315° C. Samples were periodically removed and weighed. The weight loss is converted into a recession rate based on the density of the material and the dimensions of the samples and the relative values reported in FIG. 1 are after 500 hours of exposure. As can be seen, the HfO₂ exhibits a significant improvement over BSAS.

### EXAMPLE 2

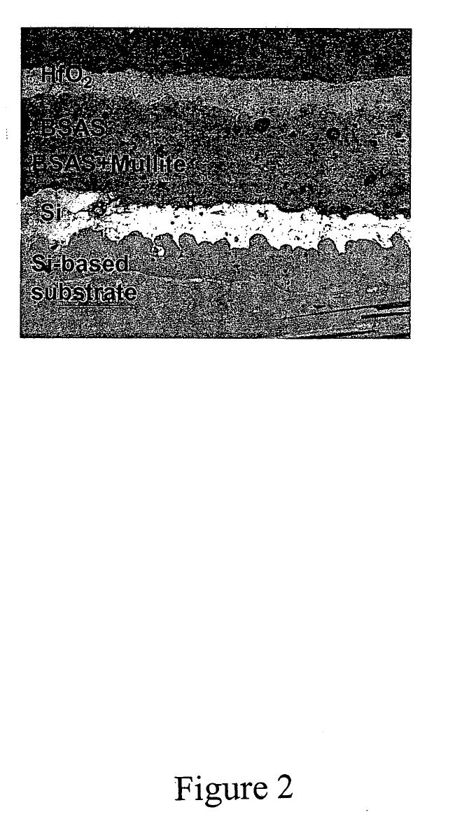

Multi layer EBC shown in FIG. 2 was prepared by Air Plasma Spray (APS). The substrate was held at a temperature of between 650 and 1100° C. during the application of the entire coating system. The first 3 layers is a standard 3-layer BSAS based EBC with a Si bond coat a mixed mullite/BSAS intermediate layer (80% mullite and 20% BSAS) and a BSAS top layer. The first 3-layers were allowed to soak in the furnace at temperature of 1100° C. for approximately 1% hour before the application of the HfO2 layer for the structure to crystallize and equilibrate. The HfO2 was applied at when the substrate was at 1100° C. Post spraying the coating went through a 1250° C./24 hr heat treat. XRD confirmed the coating to be monoclinic HfO2. The coatings were layers were approximately 4-5 mils each and were well adhered to each other.

This invention may be embodied in other forms or carried out in other ways without departing from the spirit or essential characteristics thereof. The present embodiment is therefore to be considered as in all respects illustrative and not restrictive, the scope of the invention being indicated by the appended claims, and all changes which come within the meaning and range of equivalency are intended to be embraced therein.

1. An article comprising:
a substrate comprising silicon; and
a top barrier layer comprising at least 65 mol % hafnium oxide, wherein the top barrier layer inhibits the formation of gaseous species of Si when the article is exposed to a high temperature, aqueous environment.

2. An article according to claim 1, wherein the substrate is selected from the group consisting of silicon containing ceramic materials.

3. An article according to claim 2, wherein the substrate is a silicon containing ceramic selected from the group consisting of silicon carbide and silicon nitride.

4. An article according to claim 2, wherein the substrate is a composite comprising a silicon based matrix and a reinforcing particle.

5. An article according to claim 4, wherein said substrate is selected from the group consisting of silicon carbide fiber-reinforced silicon carbide matrix, carbon fiber-reinforced silicon carbide matrix and silicon carbide fiber-reinforced silicon nitride and silicon nitride reinforced SiC

6. An article according to claim 1, wherein the top barrier layer comprises monoclinic hafnium oxide.

7. An article according to claim 1, wherein the top barrier layer further comprises up to 30 mol % of at least one of an oxide selected from the group consisting of oxides of Zr, Ti, Nb, Ta, Ce and mixtures thereof.

8. An article according to claim 1 or 7, wherein the top barrier layer further comprises up to 5 mol % of at least one of an oxide selected from the group consisting of oxides of rare earth elements, Y, Sc, Al, Si and mixtures thereof.

9. An article according to claim 8, wherein the rare earth elements are selected from the group consisting of La, Gd, Sm, Lu, Yb, Er, Pr, Pm, Dy, Ho, Eu and mixtures thereof.

10. An article according to claim 1, wherein the coefficient of thermal expansion of the top barrier layer is within ±3.0 ppm/° C. the coefficient of thermal expansion of the substrate.

11. An article according to claim 1 wherein the coefficient of thermal expansion of the top barrier layer is within ±2.0 ppm/° C. the coefficient of thermal expansion of the substrate.

12. An article according to claim 1, wherein the top barrier layer has a thickness of ≧0.5 mils (0.0005 inch), preferably 3-5 mils.

13. An article according to claim 1, including a bond layer on the substrate.

14. An article according to claim 13, wherein the bond layer comprises a constituent selected from the group consisting of a silicon metal, HfO₂, HfSiO₄ and mixtures thereof.

15. An article according to claim 1 or 13, including an intermediate layer.

16. An article according to claim 15, wherein said intermediate layer is selected from the group consisting of HfSiO₄, BaSiO₂, SrSiO₂, aluminum silicate, yttrium silicate, rare earth silicates, Alkaline earth aluminosilicates (Alkaline earth=Ba, Sr and mixtures), mullite-barium strontium aluminosilicate and mixtures thereof.

17. An article according to claim 15, wherein the intermediate layer comprises a constituent selected from the group consisting of a silicon metal, HfO₂, HfSiO₄ and mixtures thereof.

18. An article according to claim 16, wherein the intermediate layer has a thickness of ≧0.5 mils (0.0005 inch).

19. An article according to claim 12, wherein the top barrier layer has a thickness of between about 3 to 30 mils.

20. An article according to claim 12, wherein the top barrier layer has a thickness of between about up to 5 mils.

21. An article according to claim 17, wherein the intermediate layer has a thickness of 3 to 30 mils.

22. An article according to claim 17, wherein the intermediate layer has a thickness of 3 to 5 mils.

23. An article according to claim 14, wherein the bond layer has a thickness of between about 3 to 6 mils.

24. A method for preparing an article comprising the steps of:
providing a substrate comprising silicon; and
applying a top barrier layer comprising at least 65 mol % hafnium oxide to the substrate, wherein the top barrier layer inhibits the formation of gaseous species of Si when the article is exposed to a high temperature, aqueous environment.

25. A method according to claim 24, wherein the coefficient of thermal expansion of the top barrier layer is within ±3.0 ppm/° C. the coefficient of thermal expansion of the substrate.

26. A method according to claim 24, wherein the coefficient of thermal expansion of the top barrier layer is within ±0.5 ppm/° C. the coefficient of thermal expansion of the substrate.

27. A method according to claim 24, including applying the top barrier layer by thermal spraying.

28. A method according to claim 24, wherein the top barrier layer comprises monoclinic hafnium oxide.

29. A method according to claim 24, wherein the top barrier layer comprises up to 30 mol % of at least one of an oxide selected from the group consisting of oxides of Zr, Ti, Nb, Ta, Ce and mixtures thereof.

30. A method according to claim 24 or 29, wherein the top barrier layer further comprises up to 5 mol % of at least one of an oxide selected from the group consisting of oxides of rare earth elements, Y, Sc, Al, Si and mixtures thereof.

31. A method according to claim 30, wherein the rare earth elements are selected from the group consisting of La, Gd, Sm, Lu, Yb , Er, Pr, Pm, Dy, Ho, Eu and mixtures thereof.

32. A method according to claim 24, including a bond layer on the substrate.

33. A method according to claim 32, including an intermediate layer.
